(19) United States
(12) Patent Application Publication
(10) Pub. No.: US 2008/0308935 A1
(43) Pub. Date: Dec. 18, 2008

(54) SEMICONDUCTOR CHIP PACKAGE, SEMICONDUCTOR PACKAGE INCLUDING SEMICONDUCTOR CHIP PACKAGE, AND METHOD OF FABRICATING SEMICONDUCTOR PACKAGE

(75) Inventors: Young-Lyong KIM, Gyeonggi-do (KR); Eun-Chul AHN, Gyeonggi-do (KR); Jong-Ho LEE, Chungcheongnam-do (KR); Cheul-Joong YOUN, Seoul (KR); Min-Ho O, Daegu (KR); Tae-Sung YOON, Chungcheongnam-do (KR); Cheol-Joon YOO, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/141,764

(22) Filed: Jun. 18, 2008

(30) Foreign Application Priority Data
Jun. 18, 2007 (KR) 10-2007-0059595
Jun. 18, 2007 (KR) 10-2007-0059597

(51) Int. Cl. H01L 23/488; H01L 21/56

(52) U.S. Cl. 257/738; 438/127; 257/E23.023; 257/E21.502

(57) ABSTRACT

Provided are a semiconductor chip package, a semiconductor package, and a method of fabricating the same. In some embodiments, the semiconductor chip packages includes a semiconductor chip including an active surface, a rear surface, and side surfaces, bump solder balls provided on bonding pads formed on the active surface, and a molding layer provided to cover the active surface and expose portions of the bump solder balls. The molding layer between adjacent bump solder balls may have a meniscus concave surface, where a height from the active surface to an edge of the meniscus concave surface contacting the bump solder ball is about a 1/7 length of the maximum diameter of a respective bump solder ball at below or above a section of the bump solder ball having the maximum diameter.

### CROSS-REFERENCE TO RELATED APPLICATIONS

This U.S. non-provisional patent application claims priority under 35 U.S.C. §119 of Korean Patent Application Nos. 10-2007-0059595 and 10-2007-0059597, filed on Jun. 18, 2007, the entire contents of which are hereby incorporated by reference.

### BACKGROUND

The present invention disclosed herein relates to semiconductor packages and methods of fabricating the same, and more particularly, to a wafer level package and a method of fabricating the same.

### SUMMARY

The present invention provides a semiconductor chip package capable of improving a solder joint reliability and a method of fabricating the same.

The present invention also provides a semiconductor package capable of improving a solder joint reliability and a method of fabricating the same.

Embodiments of the present invention provide semiconductor chip packages that may include a semiconductor chip including an active surface, a rear surface, and side surfaces, bump solder balls provided on bonding pads formed on the active surface, and a molding layer provided to cover the active surface and expose each portion of the bump solder balls. The molding layer between adjacent bump solder balls may have a meniscus concave surface. In addition, the bump solder balls include a section parallel to the active surface having a maximum diameter, where a height from the active surface to an edge of the meniscus concave surface contacting the bump solder ball is about a 1/7 length of the maximum diameter of the bump solder ball at below or above the section of the bump solder ball having the maximum diameter.

In some embodiments, the edge of the meniscus concave surface may have a height of about 50 μm at below or above the section of the bump solder ball.

In other embodiments, the meniscus concave surface may include a first height from the active surface to the edge contacting the bump solder balls, and a second height from the active surface to a central part between the bump solder balls.

In still other embodiments, a height difference between the first height and the second height may be within about a ⅕ length of the maximum diameter of the bump solder ball.

In even other embodiments, the height difference may be at least about 10 μm between the first height and the second height.

In yet other embodiments, the meniscus concave surface may have a matted surface.

In further embodiments, the semiconductor chip may have a thickness of about 50 μm to about 760 μm.

In still further embodiments, the bump solder balls may include a solder material having a Young's modulus of about 20 GPa to about 90 GPa.

In even further embodiments, the molding layer may include an epoxy molding compound (EMC).

In yet further embodiments, the EMC may include silica of about 50 wt % to about 90 wt %.

In yet further embodiments, the EMC may have a thermal expansion coefficient of below about 50 ppm/° C. at a temperature range of less than a glass transition temperature.

In yet further embodiments, the EMC may have an elastic modulus of more than about 3 GPa.

In yet further embodiments, the molding layer may be provided to cover the side surfaces of the semiconductor chip.

In yet further embodiments, the semiconductor chip packages may further include a passivation layer provided on the rear surface of the semiconductor chip.

In yet further embodiments, the passivation layer may have a thickness of about 20 μm to about 700 μm.

In yet further embodiments, the passivation layer may be an EMC or a resin-based material.

In yet further embodiments, the passivation layer may include the same material as the molding layer.

In yet further embodiments, the semiconductor chip packages may further include a carrier layer provided on the rear surface of the semiconductor chip.

In yet further embodiments, the carrier layer may include at least one of a metal material, a ceramic material, or an organic material.

In other embodiments of the present invention, semiconductor packages may include the above semiconductor chip package, and a wiring substrate including an upper surface and a lower surface, the upper surface on which the semiconductor chip package is mounted, the lower surface facing the upper surface.

In some embodiments, the semiconductor packages may further include wiring substrate solder balls provided on the lower surface of the wiring substrate.

In still other embodiments of the present invention, methods of fabricating a semiconductor chip package may include preparing a semiconductor chip group that includes at least one semiconductor chip, the semiconductor chip including an active surface with bonding pads, a rear surface facing the active surface, and side surfaces. The method also may include forming bump solder balls on the bonding pads, and forming a molding layer to cover the active surface and expose each portion of the bump solder balls. The molding layer between adjacent bump solder balls may have meniscus concave surfaces. In addition, the bump solder balls include a section parallel to the active surface having a maximum diameter, where a height from the active surface to an edge of the meniscus concave surface contacting the bump solder ball is about a 1/7 length of the maximum diameter of the bump solder ball at below or above the section of the bump solder ball having the maximum diameter.

In yet further embodiments, the forming of the molding layer may include preparing a release tape, loading the semiconductor chip group, injecting a molding material between the release tape and the semiconductor chip group, and compressing the semiconductor chip group and the release tape, respectively.

In yet further embodiments, the release tape may be prepared between a lower mold and an upper mold, the lower mold having a molding part, the upper mold facing the lower mold and having a mounting part. The molding material may also be injected into the molding part to be provided on the release tape, the semiconductor chip group may be loaded into the mounting part, and the compressing of the semiconductor chip group and the release tape may include contacting the upper mold and the lower mold.

In yet further embodiments, the release tape may be prepared between a lower mold and an upper mold, the lower mold having a molding part, the upper mold facing the bottom die, the semiconductor chip group is loaded into the mounting part, the molding material may be injected on the molding part to be provided on the bump solder balls, and the compressing of the semiconductor chip group and the release tape may include contacting the upper mold and the lower.

In yet further embodiments, a thickness of the release tape may be greater than a value subtracting the second height of the molding layer from the height of the bump solder ball.

In yet further embodiments, the release tape may have a matted surface.

In yet further embodiments, the release tape may be a polytetrafluoroethylene (PTFE) or an ethylene tetrafluoroethylene (ETFE) copolymer.

In yet further embodiments, the release tape may have an elongation of about 10% to about 900% and a tensile stress of below about 50 MPa.

In yet further embodiments, the EMC may have a powder form or a liquid form.

In yet further embodiments, the methods may further include pre-heating and vacuum-discharging the molding part after the injecting of the molding material.

In yet further embodiments, the methods may further include forming a passivation layer on the rear surface of the polished semiconductor chip.

In yet further embodiments, the methods may further include forming a carrier layer on the rear surface of the polished semiconductor chip.

In yet further embodiments, if the semiconductor chip group includes a plurality of semiconductor chips, the semiconductor chip group may have one of a wafer form, a strip form, and a carrier mounted form, the wafer form having scribe lanes between the semiconductor chips.

In yet further embodiments, the methods may further include cutting the scribe lane between the semiconductor chips and the molding layer to separate into each semiconductor chip package.

In even other embodiments of the present invention, methods of fabricating a semiconductor package may include preparing a semiconductor chip package fabricated using the above method, preparing a wiring substrate having an upper surface and a lower surface, the upper surface on which the semiconductor chip package is mounted, the lower surface facing the upper surface, and mounting the semiconductor chip package on the upper surface of the wiring substrate.

In some embodiments, the methods may further include forming wiring substrate solder balls on the lower surface.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross-sectional view of a semiconductor chip package according to an embodiment of the present invention;

FIG. 2 is an enlarged cross-sectional view taken along the dotted circle A of FIG. 1;

FIG. 3 is a flowchart illustrating a method of fabricating a semiconductor chip package according to an embodiment of the present invention;

FIGS. 4A through 4C are cross-sectional views illustrating a method of fabricating a semiconductor chip package according to an embodiment of the present invention;

FIG. 5 is an enlarged cross-sectional view of the portion B of FIG. 4C;

FIGS. 6A through 6C are cross-sectional views illustrating a method of fabricating a semiconductor chip package according to another embodiment of the present invention;

FIGS. 7A through 7C are plan views of a semiconductor chip group according to an embodiment of the present invention;

FIGS. 8 through 12 are cross-sectional views of a semiconductor chip packages according to other embodiments of the present invention; and

FIG. 13 is a cross-sectional view illustrating a semiconductor package according to an embodiment of the present invention.

### DETAILED DESCRIPTION

Hereinafter, exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

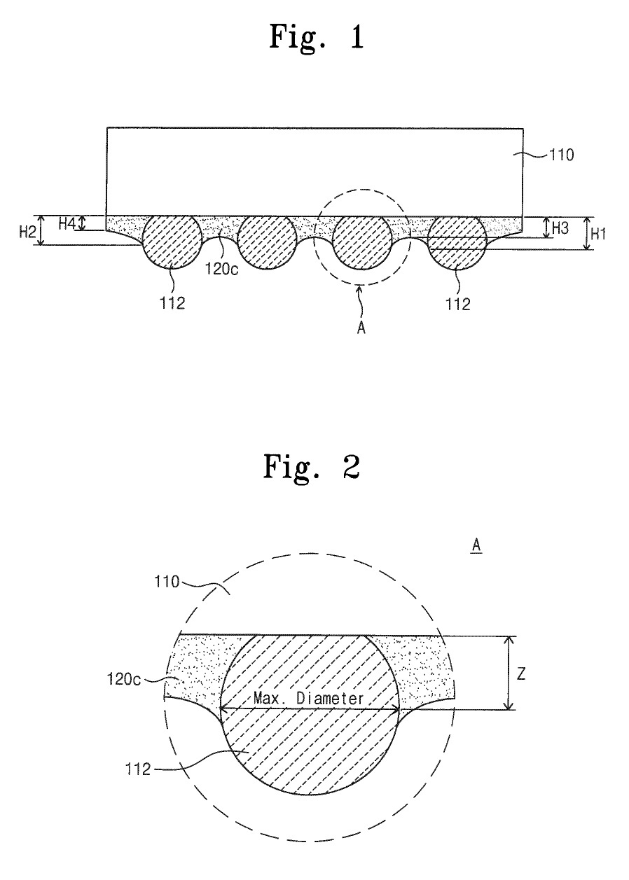

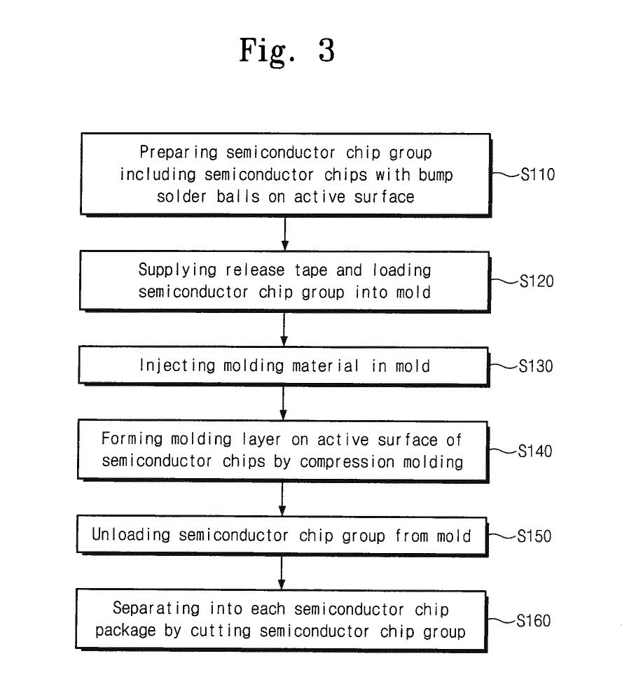

FIG. 1 is a cross-sectional view of a semiconductor chip package according to an embodiment of the present invention. FIG. 2 is an enlarged cross-sectional view taken along the dotted circle A of FIG. 1.

Referring to FIGS. 1 and 2, the semiconductor chip package may include a semiconductor chip 110, bump solder balls 112, and a molding layer 120c.

The semiconductor chip 110 may include an active surface including bonding pad (not shown), a rear surface facing the active surface, and side surfaces. In FIG. 1 the active surface may be the illustrated lower surface of the chip 110, on which the bump solder balls 112 and molding layer 120c are formed. The semiconductor chip 110 may be a memory chip or a logic chip. The semiconductor chip 110 may have a thickness ranging from about 50 μm to about 760 μm. Preferably, the semiconductor chip 110 may have a thickness ranging from about 50 μm to about 200 μm. Because the semiconductor chip 110 has a relatively thin thickness, the semiconductor chip package can be thinly formed.

The bump solder balls 112 may be provided on the bonding pads of the semiconductor chip 110. The bump solder balls 112 may include a solder material having a Young's modulus of about 20 GPa to about 90 GPa. The bump solder balls 112 may electrically connect the semiconductor chip 110 to an external circuit (e.g., a wiring substrate).

The molding layer 120c may substantially cover the active surface of the semiconductor chip 110 and expose portions of the bump solder balls 112. The molding layer 120c may have meniscus concave surfaces, including an edge that contacts the bump solder balls 112, between adjacent bump solder balls 112 and between the bump solder balls 112 and the edges of the semiconductor chip 110. The bump solder balls 112 may include a section parallel to the active surface of the semiconductor chip 110 that has a maximum diameter (shown as Max. Diameter). A height H1 from the active surface of the semiconductor chip 110 to the edge of the meniscus concave surface contacting the bump solder balls 112 may be less than about a 1/7 length of the maximum diameter of the bump solder balls 112 at below or above a height Z from the active surface of the semiconductor chip 110 to the section of the bump solder ball 112 having the maximum diameter. For example, if the maximum diameter of the bump solder ball 112 is about 350 μm, the height H1 from the active surface of the semiconductor chip 110 to the edge of the meniscus concave surface may be within about ±50 μm from the height Z that is from the active surface of the semiconductor chip 110 to the section of the bump solder ball 112. Accordingly, the active surface of the semiconductor chip 110 is protected by the molding layer 120c from chemical/physical external environments.

Because adhesive characteristic of the bump solder balls 112 is improved by the molding layer 120c, thermal stress concentrated on the bump solder balls 112 and joint portions of the semiconductor chip package can be dispersed. Therefore, the solder joint reliability (SJR) of the bump solder balls 112 can be enhanced. Additionally, the molding layer 120c may reduce a thermal expansion coefficient difference between the semiconductor chip 110 and a wiring substrate. Accordingly, the SJR of the bump solder balls 112 may be improved during a process of mounting the semiconductor chip package on the wiring substrate.

The meniscus concave surface of the molding layer 120c may include a first height H1, a second height H2, a third height H3, and a fourth height H4. The first height H1 may be from the active surface of the semiconductor chip 110 to the edge contacting the bump solder balls 112. The second height H2 may be from the active surface of the semiconductor chip 110 to a portion contacting the outermost bump solder balls 112 among the bump solder balls 112. The third height H3 may be from the active surface of the semiconductor chip 110 to the middle between adjacent bump solder balls 112. The fourth height H4 may be from the active surface of the semiconductor chip 110 to a portion corresponding to the edge of the semiconductor chip 110. There may be a height difference within about a ⅕ length of the maximum diameter of the bump solder ball 112 between the first height H1 and the third height H3. For example, if the maximum diameter of the bump solder ball 112 is about 350 μm, there may be a height difference of about 70 μm between the first height H1 and the third height H3. The second height H2 may be higher or lower than the first height H1, and the fourth height H4 may be higher or lower than the third height H3. Additionally, there may be a height difference of at least about 10 μm between the second height H2 and the fourth height H4.

The molding layer 120c may have the height H1 below or above the height Z from the active surface of the semiconductor chip 110 to the section of the maximum diameter of the bump solder ball 112. The height H1 may be within about a 1/7 length of the maximum diameter of the bump solder balls 112. As a result, the adhesive characteristic of the bump solder balls 112 can be improved. Accordingly, because a thermal stress concentrated on the bump solder balls 112 and joint portions of the semiconductor chip package are dispersed, the SJR can be improved.

If the height H1 from the active surface of the semiconductor chip 110 to the edge of the meniscus concave surface contacting the bump solder balls 112 is higher than the height Z from the active surface of the semiconductor chip 110 to the section having the maximum diameter of the bump solder ball 112 (that is, greater than about a 1/7 length of the maximum diameter of the bump solder ball 112), defects such as voids developed during a process of forming the molding layer 120c may be caused. Additionally, because the exposed surfaces of the bump solder balls 112, which is used to electrically connect the semiconductor chip 110 with an external circuit, may not be sufficient in size, the electrical reliability may be deteriorated.

If the height H1 from the active surface of the semiconductor chip 110 to the edge of the meniscus concave contacting the bump solder balls 112 is lower than the height Z from the active surface of the semiconductor chip 110 to the section having the maximum diameter of the bump solder ball 112 (that is, less than about a 1/7 length of the maximum diameter of the bump solder ball 112), the adhesive characteristic of the bump solder balls 112 provided on the bonding pads of the semiconductor chip 110 may be deteriorated. Accordingly, the SJR of the bump solder balls 112 may be deteriorated during a process of mounting the semiconductor chip package on the wiring substrate.

Thus, depending on design constraints, it may be preferable to form the molding layer 120c such that height H1 from the active surface of the semiconductor chip 110 to the edge of the meniscus concave contacting the bump solder balls 112 is substantially similar to the height Z from the active surface of the semiconductor chip 110 to the section having the maximum diameter of the bump solder ball 112 (that is, less than about a 1/7 length of the maximum diameter of the bump solder ball 112). In some embodiments, the difference in height between H1 and Z is preferably about 50 μm or less.

The meniscus concave surface of the molding layer 120c may have a matted or non-matted surface. It may be preferable in some embodiments for the meniscus concave surface of the molding layer 120c to have a matted surface. In such cases, because the meniscus concave surface of the molding layer 120c has low reflectivity due to the rough surface associated with the matted surface, the bump solder balls 112 may be easily distinguished from the surface of the molding layer 120c by the unaided eye during a process of examining the semiconductor chip package.

The molding layer 120c may include an epoxy molding compound (EMC). The EMC may include silicon (SiO₂) of about 50 wt % to about 90 wt %. The EMC may have an elastic modulus of more than 3 GPa at a temperature range of below a glass transition temperature Tg.

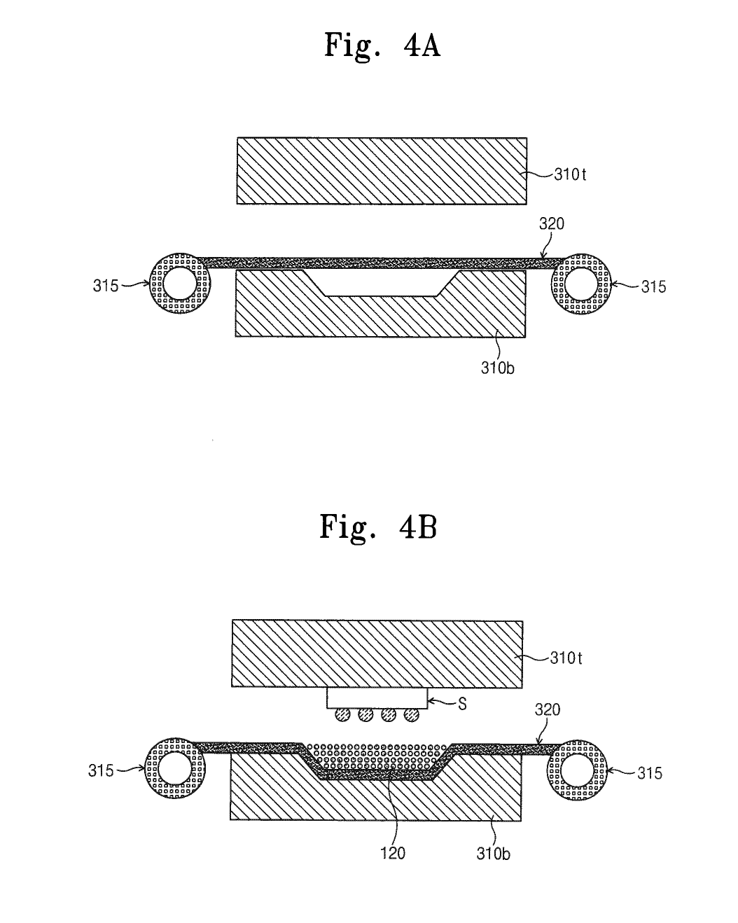

FIG. 3 is a flowchart illustrating a method of fabricating a semiconductor chip package according to an embodiment of the present invention.

Referring to FIG. 3, the method of fabricating a semiconductor chip package includes: preparing a semiconductor chip group that includes semiconductor chips with bump solder balls on an active surface in operation S110; supplying a release tape and loading the semiconductor chip group into a mold in operation S120; injecting a molding material into the mold in operation S130; forming a molding layer on the active surfaces of the semiconductor chips by compression molding in operation S140; unloading the semiconductor chips from the mold in operation S150; and cutting the semiconductor chip group to separate it into each semiconductor chip package in operation S160.

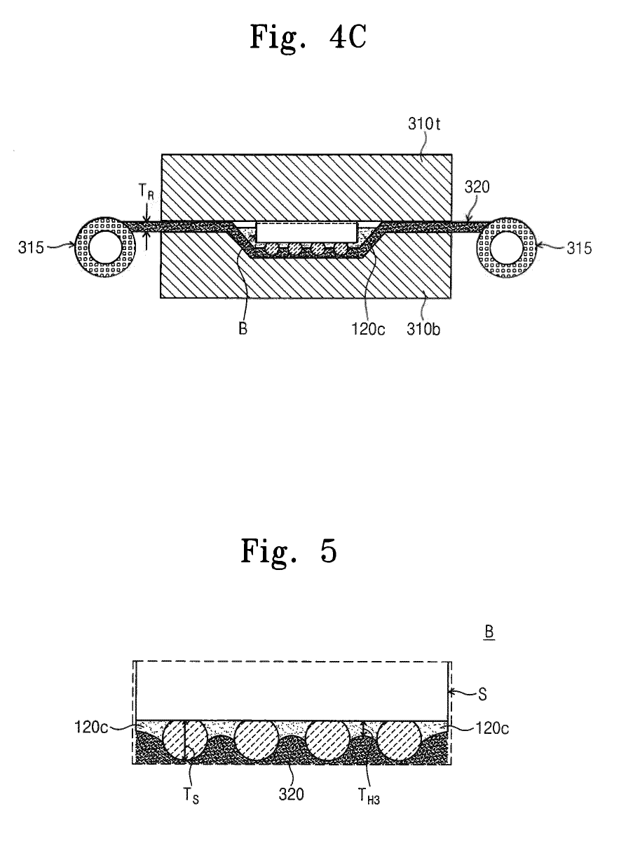

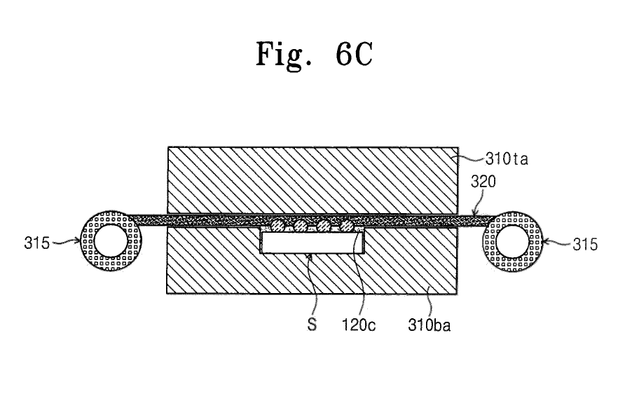

The above-mentioned method of fabricating a semiconductor chip package is described with a schematic outline flow, and its detailed description will be made with reference to FIGS. 4A through 4C or FIGS. 6A through 6C.

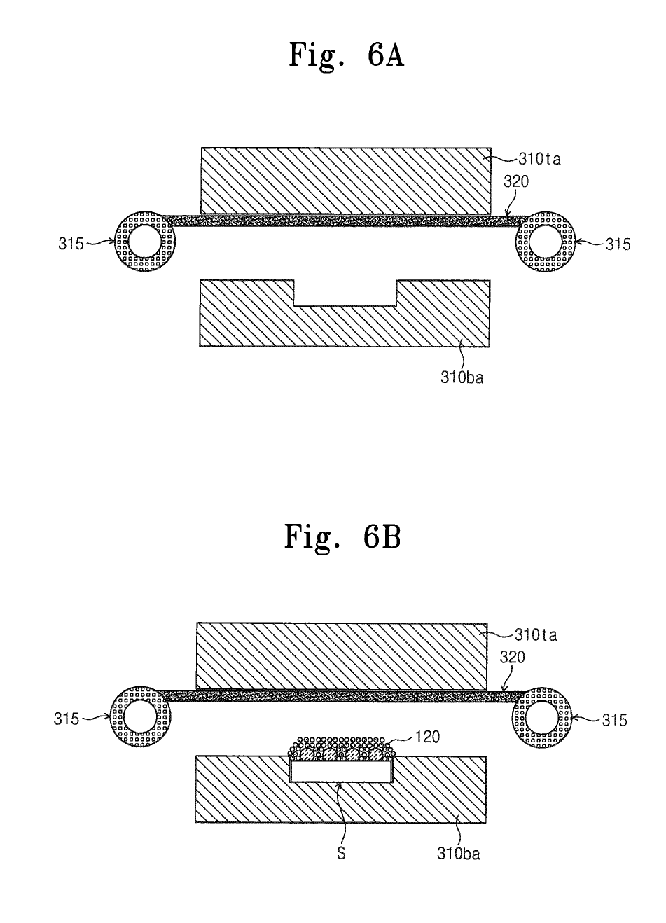

FIGS. 4A through 4C are cross-sectional views illustrating a method of fabricating a semiconductor chip package according to an embodiment of the present invention. FIG. 5 is an enlarged cross-sectional view of the portion B of FIG. 4C.

Referring to FIG. 4A, a mold may include a lower mold 310b and an upper mold 310t. The lower mold 310b may include a molding part (the concave portion in 310b). The upper mold 310t may include a mounting part. The mold may have a function that applies heat up to about 175° C. for liquefying a molding material (see 120 of FIG. 4B).

A release tape 320 may be provided between the lower mold 310b and the upper mold 310t. The release tape 320 may be provided on the lower mold 310b through a tape roller 315 having portions installed at the both sides of the lower mold 310b. The release tape 320 may be a material that is not transformed at a temperature of the molding process. For example, the release tape 320 may be a polytetrafluoroethylene (PTFE) or an ethylene tetrafluoroethylene (ETFE) copolymer.

Referring to FIG. 4B, a semiconductor chip group S with bump solder balls may be loaded into the mounting part of the upper mold 310t. The semiconductor chip group S may include at least one semiconductor chip. The semiconductor chip may include an active surface including bonding pads (not shown), a rear surface facing the active surface, and side surfaces. If the semiconductor chip group S includes a plurality of semiconductor chips, it may be one of a wafer form having scribe lanes between the semiconductor chips, a strip form, or a carrier mounted form. The rear surface of the semiconductor chip may be loaded facing the mounting part of the upper mold 301t.

The semiconductor chip group S may be loaded into the mounting part of the upper mold 310t using an adhesive material layer as a medium. The adhesive material layer may be a reworkable adhesive material that is easily detached after being attached so that the semiconductor chip group S may be unloaded after the molding process is completed. For example, the adhesive material layer may be an adhesive tape including ultraviolet (UV) curable resin or a thermoplastic resin.

Before loading the semiconductor chip group S into the upper mold 310t, the rear surface of the semiconductor chip may be polished. The polished semiconductor chip may have a thickness ranging from about 50 μm to about 570 μm. Because the semiconductor chip has a relatively thin thickness, the semiconductor chip package can be thinly formed.

After polishing the rear surface of the semiconductor chip, a passivation layer may be further formed on the rear surface of the polished semiconductor chip. The passivation layer may protect the rear surface of the semiconductor chip from chemical/physical external environments. The passivation layer may have a thickness ranging from about 20 μm to about 700 μm. The passivation layer may be, for example, an epoxy molding compound (EMC) or a resin-based material.

Additionally, a carrier layer may be further formed on the rear surface of the polished semiconductor chip. The carrier layer may serve to alleviate physical stress applied to the semiconductor chip during a process of fabricating the semiconductor chip package. The carrier layer may include at least one of a metal material, a ceramic material, or an organic material.

After closely pressing the release tape 320 on the molding part of the lower mold 310b, a molding material 120 may be injected on the molding part including the contacted release tape 320. The molding material 120 may include the EMC. The EMC may have a powder form or a liquid form. The EMC may include silica ranging from about 50 wt % to about 90 wt %. The EMC may have a thermal expansion coefficient below about 50 ppm/° C. at a temperature range of less than a glass transition temperature Tg. Accordingly, the bump solder balls of the semiconductor chip group S, loaded into the mounting part of the upper mold 310t, is disposed over the molding material 120.

After injecting the molding material 120, the molding part of the lower mold 310b may be further pre-heated and vacuum-discharged. The pre-heating may be to change the molding material 120 of the powder form into a liquid state. The pre-heating process may be performed over about 2 sec at a temperature of about 175° C. The vacuum discharge may prevent an uneven or incomplete molding layer 120c from occurring during the forming of the molding layer 120c of FIG. 4C. The vacuum discharge may be performed to make the inner pressure of the molding part of the lower mold 310b below about 50 torr.

Referring to FIGS. 4C and 5, the molding layer 120c may be formed on the active surface of the semiconductor chip through a compression molding process. The compression molding process may include pressing the semiconductor chip group S toward the liquid molding material 120 and the release tape 320. The compression may closely press the upper mold 310t and the lower mold 310b. This compression may closely contact the upper mold 310t and the lower mold 310b through the release tape 320 therebetween by moving the upper mold 310t and/or the lower mold 310b. After forming the molding layer 120c, an additional hardening process of applying a temperature of more than about 100° C. may be performed to simultaneously improve the adhesive strength between the molding layer 120c and the active surface of the semiconductor chip and increase the stability of the molding layer 120c.

Due to the compression molding, the molding layer 120c may be formed to cover the active surface of the semiconductor chip and expose portions of the bump solder balls. The molding layer 120c may include the meniscus concave surfaces described above. The bump solder balls may include a section parallel to the active surface of the semiconductor chip and having the maximum diameter. The height H1 of FIG. 1 from the active surface of the semiconductor chip to the edge of the meniscus concave surface contacting the bump solder balls may be within about a 1/7 length of the maximum diameter of the bump solder ball at below or above the height from the active surface of the semiconductor chip to the section of the bump solder ball having the maximum diameter. Accordingly, the active surface of the semiconductor chip may be protected by the molding layer 120c from chemical/physical external environments.

Because adhesive characteristic of the bump solder balls is improved by the molding layer 120c, thermal stress concentrated on the bump solder balls and joint portions of the semiconductor chip package may be dispersed. Accordingly, the solder joint reliability (SJR) of the bump solder balls can be enhanced. Additionally, the molding layer 120c may reduce a thermal expansion coefficient difference between the semiconductor chip and a wiring substrate. Accordingly, the SJR of the bump solder balls may be improved during a process of mounting the semiconductor chip package on the wiring substrate.

Furthermore, the molding layer 120c may improve the strength of the semiconductor chip group S such that chipping phenomenon, in which the edge of the semiconductor chip package is chipped, can be minimized during a subsequent cutting process for separating the semiconductor chip group S into each semiconductor chip package. Accordingly, deterioration of the semiconductor chip package due to the cutting process can be prevented.

The formation of the meniscus concave surfaces in the molding layer 120c may be caused by the release tape 320 interposed between the upper mold 310t and the lower mold 310b. This may be due in part because each portion of the bump solder balls may be depressed by the release tape 320 during the compression molding. Accordingly, the release tape 320 may form meniscus convex surfaces between the respectively adjacent bump solder balls. Consequently, the molding layer 120c may have the meniscus concave surfaces pressed by the meniscus convex surfaces of the release tape 320.

The thickness T_{R} of the release tape 320 may be larger than a value subtracting the third height T_{H3} (the same as H3 of FIG. 1) of the molding layer 120c from the height T_{S} of the bump solder balls. The release tape 320 may have an elongation of about 10% to about 900% and a tensile stress of below about 50 MPa. If the tensile stress of the release tape 320 is more than about 50 MPa, the bump solder balls having a solder material of the Young's modulus of about 20 GPa to about 900 GPa may be pressed by the release tape 320 and thus their shape may be deformed.

The meniscus concave surface may include a first height, a second height, a third height, and a fourth height. The first height (referring to H1 of FIG. 1) may be from the active surface of the semiconductor chip to the edge contacting the bump solder balls. The second height (referring to H2 of FIG. 1) may be from the active surface of the semiconductor chip to a portion contacting the outermost bump solder balls among the bump solder balls. The third height (referring to H3 of FIG. 1) may be from the active surface of the semiconductor chip to the middle between adjacent bump solder balls. The fourth height (referring to H4 of FIG. 1) may be from the active surface of the semiconductor chip to a portion corresponding to the edge of the semiconductor chip. There may be a height difference within about a ⅕ length of the maximum diameter of the bump solder ball between the first height and the third height. For example, there may be a height difference of at least about 10 μm between the first height and the third height. The second height may be higher or lower than the first height, and the fourth height may be higher or lower than the third height. Additionally, there may be a height difference of at least about 10 μm between the second height and the fourth height.

The molding layer 120c may have the height below or above the height from the active surface of the semiconductor chip to the section of the maximum diameter of the bump solder ball. The height may be within about a 1/7 length of the maximum diameter of the bump solder ball. As a result, adhesive characteristic of the bump solder balls can be improved. Accordingly, because a thermal stress concentrated on the bump solder balls and joint portions of the semiconductor chip package is dispersed, the SJR can be improved.

If the height from the active surface of the semiconductor chip to the edge of the meniscus concave surface contacting the bump solder balls is higher than the height from the active surface of the semiconductor chip to the section having the maximum diameter of the bump solder ball (that is, greater than about a 1/7 length of the maximum diameter of the bump solder ball), defects such as voids developed during a process of forming the molding layer 120c may be caused. Additionally, because the exposed surfaces of the bump solder balls 112, which are used to electrically connect the semiconductor chip with an external circuit, may not be sufficient in size, the electrical reliability may be deteriorated.

If the height from the active surface of the semiconductor chip to the edge of the meniscus concave surface contacting the bump solder balls is lower than the height from the active surface of the semiconductor chip to the section having the maximum diameter of the bump solder ball (that is, less than about a 1/7 length of the maximum diameter of the bump solder ball), the adhesive characteristic of the bump solder balls provided on the bonding pads of the semiconductor chip may be deteriorated. Accordingly, the SJR of the bump solder balls may be deteriorated during a process of mounting the semiconductor chip package on the wiring substrate.

The release tape 320 may have a matted or non-matted surface. The surface of the release tape 320 may be projected on the meniscus concave surfaces of the molding layer 120c during a molding process. Accordingly, the meniscus concave surfaces of the molding layer 120c may have a matted or non-matted surface. It may be preferable in some embodiments for the meniscus concave surfaces of the molding layer 120c to have a matted surface. In such cases, because the meniscus concave surfaces of the molding layer 120c has low reflectivity due to the rough surface associated with the matted surface, the bump solder balls are easily distinguished from the surface of the molding layer 120c by the unaided eye during a process of examining the semiconductor chip package.

The molding layer 120c may be further formed to cover the side surfaces of the semiconductor chip. This is done by changing the form of the molding part of the lower mold 310b, or mounting the separated semiconductor chip unit on a carrier. Accordingly, the side surfaces of the semiconductor chip may be protected by the molding layer 120c from chemical/physical external environments.

Although not illustrated, after unloading the semiconductor chip group S with the molding layer 120c from the upper mold 310t, the semiconductor chip packages may be separated by cutting the scribe lanes and the molding layer 120c between the semiconductor chips. Accordingly, the fabricated semiconductor chip package may include the molding layer 120c with the meniscus concave surfaces cover the active surface of the semiconductor chip and expose a portion of each bump solder ball.

FIGS. 6A through 6C are cross-sectional views illustrating a method of fabricating a semiconductor chip package according to another embodiment of the present invention.

Referring to FIG. 6A, a mold may include a lower mold 310ba and an upper mold 310ta. The lower mold 310ba may include a molding part (the concave portion in 310ba) with a mounting part. The mold may have a function that applies heat up to about 175° C. for liquefying a molding material (see 120 of FIG. 6B).

A release tape 320 may be provided between the lower mold 310ba and the upper mold 310ta. The release tape 320 may be provided to the upper mold 310ta through a tape roller 315 with portions installed at the both sides of the upper mold 310ta.

Referring to FIG. 6B, a semiconductor chip group S with bump solder balls may be loaded into the lower mold 310ba. The semiconductor chip group S may include at least one semiconductor chip. The semiconductor chip may include an active surface including bonding pads (not shown), a rear surface facing the active surface and side surfaces. If the semiconductor chip group S includes a plurality of semiconductor chips, it may be one of a wafer form having scribe lanes between the semiconductor chips, a strip form, or a carrier mounted form. The rear surface of the semiconductor chip may be loaded facing the mounting part of the lower mold 310ba.

The semiconductor chip group S may be loaded into the mounting part of the lower mold 310ba by using an adhesive material layer as a medium. The adhesive material layer may be a reworkable adhesive material that is easily detached after being attached so that the semiconductor chip group S may be unloaded after a molding process is completed.

Before loading the semiconductor chip group S into the lower mold 310ba, the rear surface of the semiconductor chip may be polished. The polished semiconductor chip may have the thickness ranging from about 50 μm to about 760 μm. Because the semiconductor chip has a relatively thin thickness, the semiconductor chip package can be thinly formed. After polishing the rear surface of the semiconductor chip, a passivation layer may be further formed on the rear surface of the polished semiconductor chip. The passivation layer may protect the rear surface of the semiconductor chip from chemical/physical external environments. The passivation layer may have a thickness ranging from about 20 μm to about 700 μm.

Additionally, a carrier layer may be further formed on the rear surface of the polished semiconductor chip. The carrier layer may serve to alleviate physical stress applied to the semiconductor chip during a process of fabricating the semiconductor chip package.

After closely pressing the release tape 320 on the upper mold 310ta, a molding material 120 may be injected on the molding part of the lower mold 310ba to cover the bump solder balls of the semiconductor chip group S loaded into the mounting part of the lower mold 310ba. The molding material 120 may include an epoxy molding compound (EMC). The EMC may have a powder form or a liquid form. Accordingly, the molding material 120 may be placed on the bump solder balls of the semiconductor chip group S loaded into the mounting part of the lower mold 310ba.

After injecting the molding material 120, the molding part of the lower mold 310ba may be further pre-heated and vacuum-discharged. The pre-heating may be to change the molding material 120 of the powder form into a liquid state. The pre-heating process may be performed over about 2 sec at a temperature of about 175° C. The vacuum discharge may prevent an uneven or incomplete molding layer 120c from occurring during the forming of the molding layer 120c of FIG. 6C. The vacuum discharge may be performed to make the inner pressure of the molding part of the lower mold 310ba below about 50 torr.

Referring to FIG. 6C, the molding layer 120c may be formed on the active surface of the semiconductor chip through a compression molding process. The compression molding process may include pressing the release tape 320 toward the liquid molding material 120 on the semiconductor chip group S. The compression may closely press the upper mold 310ta and the lower mold 310ba. This compression may closely contact the upper mold 310ta and the lower mold 310ba through the release tape 320 therebetween by moving the upper mold 310ta and/or the lower mold 310ba. After forming the molding layer 120c, an additional hardening process of applying a temperature of more than about 100° C. may be performed to simultaneously improve the adhesive strength between the molding layer 120c and the active surface and increase the stability of the molding layer 120c.

Due to the compression molding, the molding layer 120c may be formed to cover the active surface of the semiconductor chip and expose portions of the bump solder balls. The molding layer 120c may include the meniscus concave surfaces described above. The bump solder balls may include a section parallel to the active surface of the semiconductor chip and having the maximum diameter. The height (referring to H1 of FIG. 1) from the active surface of the semiconductor chip to the edge of the meniscus concave surface contacting the bump solder balls is within about a 1/7 length of the maximum diameter of the bump solder ball at below or above the height from the active surface to the section of the bump solder ball having the maximum diameter. Accordingly, the active surface of the semiconductor chip may be protected by the molding layer 120c from chemical/physical external environments.

Because adhesive characteristic of the bump solder balls is improved by the molding layer 120c, thermal stress concentrated on the bump solder balls and joint portions of the semiconductor chip package may be dispersed. Accordingly, the solder joint reliability (SJR) of the bump solder balls can be enhanced. Additionally, the molding layer 120c may reduce a thermal expansion coefficient difference between the semiconductor chip and a wiring substrate. Accordingly, the SJR of the bump solder balls may be improved during a process of mounting the semiconductor chip package on the wiring substrate.

Furthermore, the molding layer 120c may improve the strength of the semiconductor chip group S such that chipping phenomenon, in which the edge of the semiconductor chip package is chipped, can be minimized during a subsequent cutting process for separating into each semiconductor chip package. Accordingly, deterioration of the semiconductor chip package due to the cutting process can be prevented.

The formation of the meniscus concave surfaces in the molding layer 120c may be caused by the release tape 320 interposed between the upper mold 310ta and the lower mold 310ba. This may be due in part because each portion of the bump solder balls may be depressed by the release tape 320 during the compression molding. Accordingly, the release tape 320 may form meniscus convex surfaces between the respectively adjacent bump solder balls. Consequently, the molding layer 120c may have the meniscus concave surfaces pressed by the meniscus convex surfaces of the release tape 320.

The meniscus concave surfaces may include a first height, a second height, a third height, and a fourth height. The first height (referring to H1 of FIG. 1) may be from the active surface of the semiconductor chip to the edge contacting the bump solder balls. The second height (referring to H2 of FIG. 1) may be from the active surface of the semiconductor chip to a portion contacting the outermost bump solder balls among the bump solder balls. The third height (referring to H3 of FIG. 1) may be from the active surface of the semiconductor chip to the middle between adjacent bump solder balls. The fourth height (referring to H4 of FIG. 1) may be from the active surface of the semiconductor chip to a portion corresponding to the edge of the semiconductor chip. There may be a height difference within about a ⅕ length of the maximum diameter of the bump solder ball between the first height and the third height. For example, there may be a height difference of at least about 10 μm between the first height and the third height. The second height may be higher or lower than the first height, and the fourth height may be higher or lower than the third height. Additionally, there may be a height difference of at least about 10 μm between the second height and the fourth height.

The molding layer 120c may have the height below or above the height from the active surface of the semiconductor chip to the section of the maximum diameter of the bump solder ball. The height may be within about a 1/7 length of the maximum diameter of the bump solder ball. As a result, adhesive characteristic of the bump solder balls can be improved. Accordingly, because a thermal stress concentrated on the solder balls for a bump and joints of the semiconductor chip package is dispersed, the SJR can be improved.

If the height from the active surface of the semiconductor chip to the edge of the meniscus concave surfaces contacting the bump solder balls is higher than the height from the active surface of the semiconductor chip to the section having the maximum diameter of the bump solder ball (that is, greater than about a 1/7 length of the maximum diameter of the bump solder ball), defects such as voids developed during a process of forming the molding layer 120c may be caused. Additionally, because the exposed surfaces of the bump solder balls 112, which are used to electrically connect the semiconductor chip with an external circuit, may not be sufficient in size, the electrical reliability may be deteriorated.

If the height from the active surface of the semiconductor chip to the edge of the meniscus concave surface contacting the bump solder balls is lower than the height from the active surface of the semiconductor chip to the section having the maximum diameter of the bump solder ball (that is, less than about a 1/7 length of the maximum diameter of the bump solder ball), the adhesive characteristic of the bump solder balls provided on the bonding pads of the semiconductor chip may be deteriorated. Accordingly, the SJR of the bump solder balls may be deteriorated during a process of mounting the semiconductor chip package on the wiring substrate.

The release tape 320 may have a matted or non-matted surface. The surface of the release tape 320 may be projected on the meniscus concave surfaces of the molding layer 120c during a molding process. Accordingly, the meniscus concave surfaces of the molding layer 120c may have a matted or non-matted surface. It may be preferable in some embodiments for the meniscus concave surfaces of the molding layer 120c to have a matted surface. In such cases, because the meniscus concave surfaces of the molding layer 120c has low reflectivity due to the rough surface associated with the matted surface, the bump solder balls are easily distinguished from the surface of the molding layer 120c by the unaided eye during a process of examining the semiconductor chip package.

The molding layer 120c may be further formed to cover the side surfaces of the semiconductor chip. This is done by changing the form of the molding part of the lower mold 310ba, or mounting the separated semiconductor chip unit on a carrier. Accordingly, the side surfaces of the semiconductor chip may be protected by the molding layer 120c from chemical/physical external environments.

Although not illustrated, after unloading the semiconductor chip group S with the molding layer 120c from the lower mold 310ba, the semiconductor chip packages may be separated by cutting the scribe lanes and the molding layer 120c between the semiconductor chips. Accordingly, the fabricated semiconductor chip package may include the molding layer 120c with the meniscus concave surfaces covering the active surface of the semiconductor chip and exposing a portion of each bump solder ball.

The semiconductor chip package fabricated according to the above-mentioned methods may include a molding layer covering an active surface of a semiconductor chip and exposing each portion of bump solder balls. Therefore, the active surface of the semiconductor chip may be protected from chemical/physical external environments. Additionally, because the molding layer reduces a thermal expansion coefficient between the semiconductor chip and a wiring substrate during a process of mounting the semiconductor chip package on the wiring substrate, the SJR can be improved.

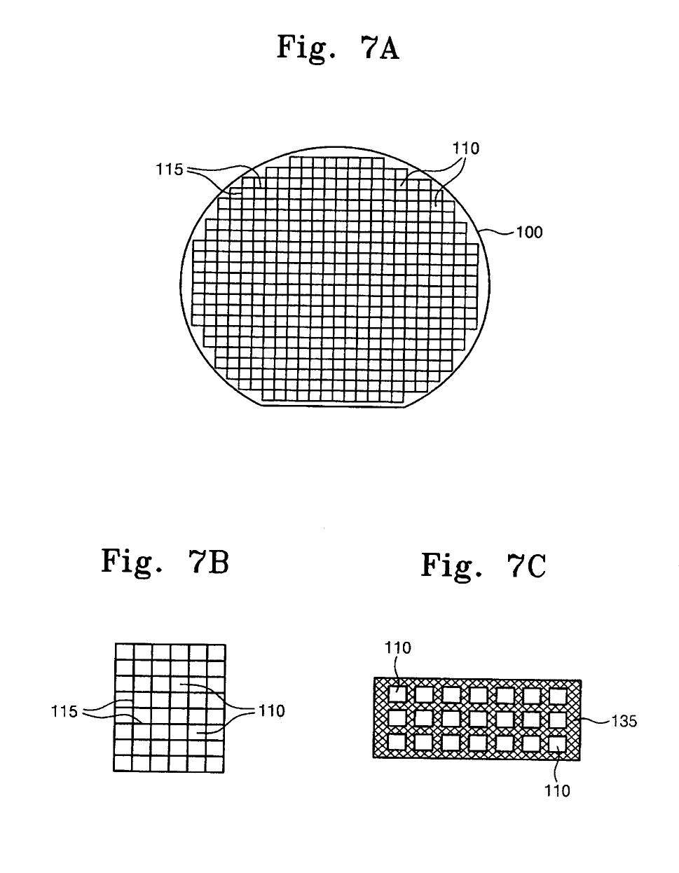

FIGS. 7A through 7C are plan views of a semiconductor chip group according to an embodiment of the present invention.

Referring to FIGS. 7A through 7C, the semiconductor chip group of a wafer form may include a plurality of semiconductor chips 110 formed on a wafer 100 and scribe lanes 115 formed between the semiconductor chips 110.

The semiconductor chip group of a strip form may be a part of a semiconductor chip group of a wafer form that is cut into an intended form as shown in the embodiment illustrated in FIG. 7B. The semiconductor chip group of a strip form may include semiconductor chips 110 and scribe lanes 115 formed therebetween.

The semiconductor chip group of a carrier mounted form may be mounted on a carrier 135 to allow each semiconductor chip 110 to have specific arrangement as shown in the embodiment illustrated in FIG. 7C. The semiconductor chip group of a carrier mounted form may include semiconductor chips 110 and the carrier 135 loaded with the semiconductor chips 110. The carrier 135 between the semiconductor chips 110 may be used as a scribe lane. The carrier 135 may have the same form and size as the wafer.

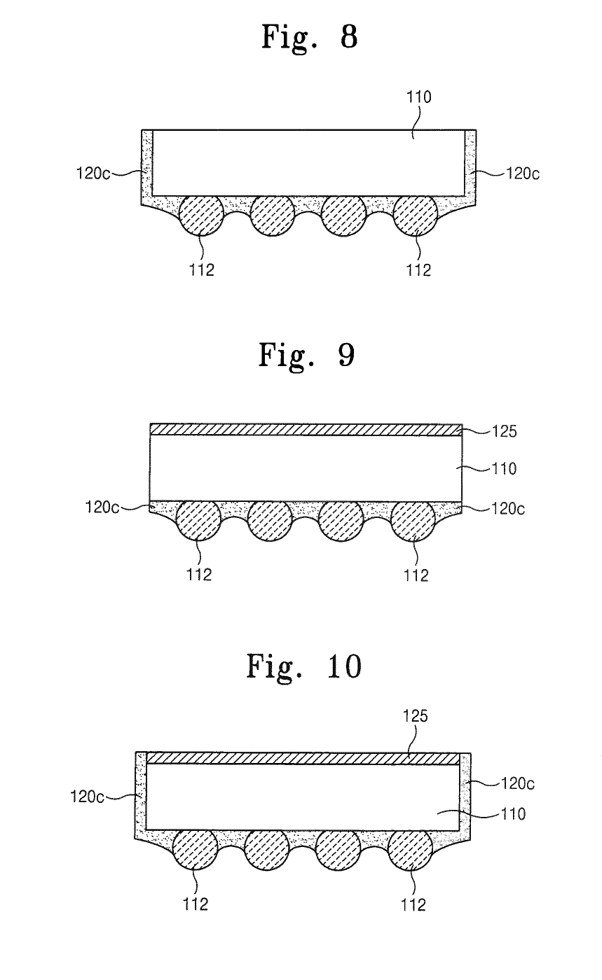

FIGS. 8 through 12 are cross-sectional views of a semiconductor chip packages according to other embodiments of the present invention.

Referring to FIG. 8, a molding layer 120c of the semiconductor chip package may be provided to cover side surfaces of a semiconductor chip 110. Accordingly, an active surface and the side surfaces of the semiconductor chip 110 may be protected by the molding layer 120c from chemical/physical external environments.

Referring to FIG. 9, the semiconductor chip package may further include a passivation layer 125 formed on a rear surface of a semiconductor chip 110. The passivation layer 125 may have a thickness ranging from about 20 μm to about 70 μm. The passivation layer 125 may be an epoxy molding compound (EMC) or a resin-based material. Accordingly, an active surface of the semiconductor chip 110 may be protected by a molding layer 120c from chemical/physical external environments, and the rear surface of the semiconductor chip 110 may be protected by the passivation layer 125 from chemical/physical external environments.

Referring to FIG. 10, a molding layer 120c of the semiconductor chip package may be provided to cover side surfaces of a semiconductor chip 110. Additionally, the semiconductor chip package may further include a passivation layer 125 provided on a rear surface of the semiconductor chip 110. The passivation layer 125 may have a thickness of about 20 μm to about 700 μm. The passivation layer 125 may be an EMC or a resin-based material. Accordingly, an active surface and the side surfaces of the semiconductor chip 110 may be protected by the molding layer 120c from chemical/physical external environments, and the rear surface of the semiconductor chip 110 may be protected by the passivation layer 125 from chemical/physical external environments.

Referring to FIG. 11, a molding layer 120 of the semiconductor chip package may be provided to cover side surfaces of a semiconductor chip 110. Additionally, the semiconductor chip package may further include a passivation layer 130 provided on a rear surface of the semiconductor chip 110. The passivation layer 130 may have a thickness of about 20 μm to about 700 μm. The passivation layer 130 may include the same material as the molding layer 120c, such as an EMC including silica. Accordingly, the active surface and the side surfaces of the semiconductor chip 110 may be protected by the molding layer 120 from chemical/physical external environments, and the rear surface of the semiconductor chip 110 may be protected by the passivation layer 130 from chemical/physical external environments.

Referring to FIG. 12, a molding layer 120 of the semiconductor chip package may be provided to cover side surfaces of a semiconductor chip 110. The semiconductor chip package may further include a carrier layer 135 provided on a rear surface of the semiconductor chip 110. The carrier layer 135 may include at least one of a metal material, a ceramic material, or an organic material. The carrier layer 135 may serve to alleviate physical stress applied to the semiconductor chip 110 during a process of forming the molding layer 120c on an active surface and the side surfaces of the semiconductor chip 110. Accordingly, the active surface and the side surfaces of the semiconductor chip 110 may be protected by the molding layer 120c from chemical/physical external environments, and the rear surface of the semiconductor chip 110 may be protected by the carrier layer 135 from chemical/physical external environments.

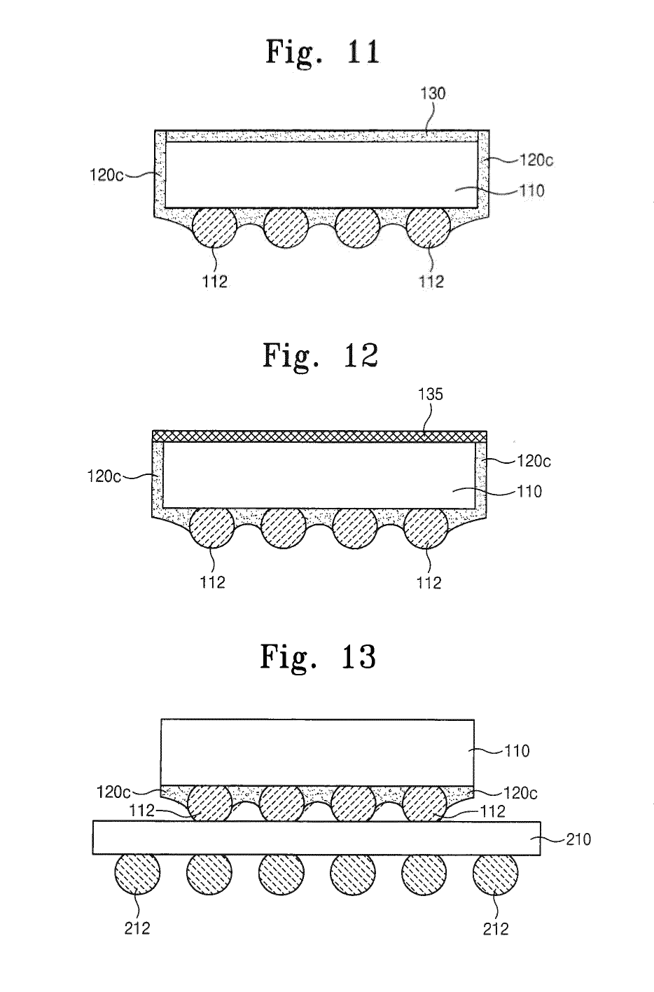

FIG. 13 is a cross-sectional view illustrating a semiconductor package according to an embodiment of the present invention.

Referring to FIG. 13, a semiconductor package may include a semiconductor chip package fabricated with similar structures to at least one of the embodiments illustrated in as FIG. 1 and FIGS. 8 through 12 by using the method of FIG. 3. The semiconductor package may also include, a wiring substrate 210, and wiring substrate solder balls 212. The semiconductor package may be manufactured by mounting the semiconductor chip package on the wiring substrate 210. The semiconductor package including the semiconductor chip package of FIG. 1 will be used as an example for the following description. However, any of the semiconductor chip packages contemplated in this disclosure may be used, including any of the semiconductor chip packages illustrated in FIGS. 8 through 12.

The semiconductor chip package may include a semiconductor chip 110, bump solder balls 112, and a molding layer 120c. The semiconductor chip 110 may include an active surface with bonding pads (not shown), a rear surface facing the active surface, and side surfaces. The bump solder balls 112 may be provided on the bonding pads of the semiconductor chip 110. The bump solder balls 112 may electrically connect the semiconductor chip 110 and the wiring substrate 210.

The molding layer 120c may substantially cover the active surface of the semiconductor chip 110 and expose portions of the bump solder balls 112. The molding layer 120c may have meniscus concave surfaces, including an edge that contacts the bump solder balls 112 between adjacent bump solder balls 112 and between the bump solder balls 112 and the edges of the semiconductor chip 110. The bump solder balls 112 may have a section parallel to the active surface of the semiconductor chip 110 that has a maximum diameter. The height (referring to H1 of FIG. 1) from the active surface of the semiconductor chip 110 to the edge of the meniscus concave surfaces contacting the bump solder balls 112 may be less than about a 1/7 length of the maximum diameter of the bump solder ball 112 at below or above the height (referring to Z of FIG. 2) from the active surface of the semiconductor chip 110 to the section of the bump solder ball 112 having the maximum diameter. Accordingly, the active surface of the semiconductor chip 110 is protected by the molding layer 120c from chemical/physical external environments.

The molding layer 120c may have the height H1 (FIG. 1) from the active surface of the semiconductor chip 110 to the edge of the meniscus concave surfaces that contacts the bump solder balls 112. The height may be within about a 1/7 length of the maximum diameter of the bump solder ball 112 at below or above the height Z (FIG. 2) from the active surface of the semiconductor chip 110 to the section of the bump solder ball 112 having the maximum diameter. Thus, adhesive characteristic of the bump solder balls 112 may be improved. Accordingly, thermal stress concentrated on the bump solder balls 112 and joint portions of the semiconductor chip package can be dispersed. Therefore, the solder joint reliability (SJR) of the bump solder balls 112 can be enhanced during a process of mounting the semiconductor chip package on the wiring substrate 210.

The wiring substrate 210 may include an upper surface on which the semiconductor chip package is mounted and a lower surface facing the upper surface. The wiring substrate 210 may be a system board including a printed circuit board (PCB). The upper surface of the wiring substrate 210 may include bonding electrodes (not shown) and the lower surface of the wiring substrate 210 may include connection electrodes (not shown). The bonding electrodes may be electrically connected to the bonding pads of the corresponding semiconductor chip 110 by using the bump solder balls 112.

The wiring substrate solder balls 212 may be provided on the connection electrodes included on the lower surface of the wiring substrate 210. The wiring substrate solder balls 212 may be connected to inner wirings (not shown) of the wiring substrate 210 to provide electrical connection between the semiconductor chip 110 and an external circuit (e.g., a main board).

The semiconductor package having the above structure may include a molding layer with meniscus concave surfaces that cover an active surface of a semiconductor chip and expose portions of bump solder balls. As a result of this configuration the active surface of the semiconductor chip may be protected by the molding layer from chemical/physical external environments. Additionally, the molding layer may reduce a thermal expansion coefficient between the semiconductor chip and a wiring substrate during a process of mounting a semiconductor chip package on the wiring substrate, the SJR can be improved. Accordingly, because the SJR of the bump solder balls is improved, the semiconductor package may have stable electrical characteristic. Furthermore, because the semiconductor package of embodiments of the present invention includes the molding layer unlike a typical semiconductor package including a molding material, semiconductor package manufacturing processes may be simplified and its manufacturing costs can be reduced.

The above-disclosed subject matter is to be considered illustrative, and not restrictive, and the appended claims are intended to cover all such modifications, enhancements, and other embodiments which fall within the spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor chip package comprising:
a semiconductor chip including a first surface, a second surface, and side surfaces, the first surface having bonding pads and the second surface facing the first surface;
bump solder balls provided on the bonding pads, the bump solder balls respectively including a section parallel to the first surface having a maximum diameter; and
a molding layer formed on the semiconductor chip to cover the first surface and expose portions of the bump solder balls, the molding layer between adjacent bump solder balls having a meniscus concave surface,
wherein a height from the first surface to an edge of the meniscus concave surface contacting a corresponding bump solder ball is about a 1/7 length of the maximum diameter of the corresponding bump solder ball at below or above the section of the bump solder ball having the maximum diameter.

2. The semiconductor chip package of claim 1, wherein the edge of the meniscus concave surface has a height of about 50 μm at below or above the section of the bump solder ball having the maximum diameter.

3. The semiconductor chip package of claim 1, wherein the meniscus concave surface comprises:
a first height from the first surface to the edge contacting the bump solder balls; and
a second height from the first surface to a central part between the bump solder balls.

4. The semiconductor chip package of claim 3, wherein a height difference between the first height and the second height is within about a ⅕ length of the maximum diameter of the bump solder ball.

5. The semiconductor chip package of claim 4, wherein the height difference is at least about 10 μm between the first height and the second height.

6. The semiconductor chip package of claim 1, wherein the meniscus concave surface has a matted surface.

7. The semiconductor chip package of claim 1, wherein the semiconductor chip has a thickness of about 50 μm to about 760 μm.

8. The semiconductor chip package of claim 1, wherein the bump solder balls comprise a solder material having a Young's modulus of about 20 GPa to about 90 GPa.

9. The semiconductor chip package of claim 1, wherein the molding layer comprises an epoxy molding compound (EMC).

10. The semiconductor chip package of claim 9, wherein the EMC comprises silica of about 50 wt % to about 90 wt %.

11. The semiconductor chip package of claim 9, wherein the EMC has a thermal expansion coefficient of below about 50 ppm/° C. at a temperature range of less than a glass transition temperature.

12. The semiconductor chip package of claim 9, wherein the EMC has an elastic modulus of more than about 3 GPa.

13. The semiconductor chip package of claim 1, wherein the molding layer is provided to cover the side surfaces of the semiconductor chip.

14. The semiconductor chip package of claim 1, further comprising a passivation layer provided on the second surface of the semiconductor chip.

15. The semiconductor chip package of claim 14, wherein the passivation layer has a thickness of about 20 μm to about 700 μm.

16. The semiconductor chip package of claim 14, wherein the passivation layer is an EMC or a resin-based material.

17. The semiconductor chip package of claim 14, wherein the passivation layer comprises substantially the same material as the molding layer.

18. The semiconductor chip package of claim 1, further comprising a carrier layer provided on the second surface of the semiconductor chip.

19. The semiconductor chip package of claim 18, wherein the carrier layer comprises at least one of a metal material, a ceramic material, or an organic material.

20. A semiconductor package comprising:
the semiconductor chip package of claim 1; and
a wiring substrate including a first surface and a second surface, the first surface on which the semiconductor chip package is mounted, the second surface facing the first surface.

21. The semiconductor package of claim 20, further comprising wiring substrate solder balls provided on the second surface of the wiring substrate.

22. A method of fabricating a semiconductor chip package, the method comprising:
preparing a semiconductor chip group that includes at least one semiconductor chip, the semiconductor chip including a first surface with bonding pads, a second surface facing the first surface, and side surfaces;
forming bump solder balls on the bonding pads, the bump solder balls each including a section parallel to the first surface and having a maximum diameter; and
forming a molding layer to cover the first surface and expose respective portions of the bump solder balls,
the molding layer between adjacent bump solder balls formed to have a meniscus concave surface,
wherein a height from the first surface to an edge of the meniscus concave surface contacting a corresponding bump solder ball is about a 1/7 length of the maximum diameter of the corresponding bump solder ball at below or above the section of the bump solder ball having the maximum diameter.

23. The method of claim 22, wherein the edge of the meniscus concave surface has a height of about 50 μm at below or above the section of the bump solder ball having the maximum diameter.

24. The method of claim 22, wherein the meniscus concave surface comprises:
a first height from the first surface to the edge contacting the bump solder balls; and
a second height from the first surface to a central part between the bump solder balls.

25. The method of claim 24, wherein a height difference between the first height and the second height is within about a ⅕ length of the maximum diameter of the bump solder ball.

26. The method of claim 25, wherein the height difference is at least about 10 μm between the first height and the second height.

27. The method of claim 22, wherein the meniscus concave surface has a matted surface.

28. The method of claim 22, further comprising polishing the second surface of the semiconductor chip.

29. The method of claim 28, wherein the polished semiconductor chip has a thickness of about 50 μm to about 760 μm.

30. The method of claim 22, wherein the bump solder balls comprise a solder material having a Young's modulus of about 20 GPa to about 90 GPa.

31. The method of claim 22, wherein the forming of the molding layer comprises:
preparing a release tape;
loading the semiconductor chip group;
injecting a molding material between the release tape and the semiconductor chip group; and
compressing the semiconductor chip group and the release tape, respectively.

32. The method of claim 31, wherein:
the release tape is prepared between a lower mold and an upper mold, the lower mold having a molding part, the upper mold facing the lower mold and having a mounting part;
the molding material is injected on the molding part to be provided on the release tape;
the semiconductor chip group is loaded into the mounting part; and
the compressing of the semiconductor chip group and the release tape includes contacting the upper mold and the lower mold.

33. The method of any one of claims 32, further comprising pre-heating and vacuum-discharging the molding part after the injecting of the molding material.

34. The method of claim 31, wherein:
the release tape is prepared between a lower mold and an upper mold, the lower mold having a molding part with a mounting part, the upper mold facing the lower mold;
the semiconductor chip group is loaded into the mounting part;
the molding material is injected on the molding part to be provided on the bump solder balls; and
the compressing of the semiconductor chip group and the release tape includes contacting the upper mold and the lower mold.

35. The method of any one of claims 34, further comprising pre-heating and vacuum-discharging the molding part after the injecting of the molding material.

36. The method of claim 31, wherein a thickness of the release tape is greater than a value subtracting the second height of the molding layer from the height of the bump solder ball.

37. The method of claim 36, wherein the release tape has a matted surface.

38. The method of claim 36, wherein the release tape is a polytetrafluoroethylene (PTFE) or an ethylene tetrafluoroethylene (ETFE) copolymer.

39. The method of claim 38, wherein the release tape has an elongation of about 10% to about 900% and a tensile stress of below about 50 MPa.

40. The method of claim 31, wherein the molding material comprises an EMC.

41. The method of claim 40, wherein the EMC has a powder form or a liquid form.

42. The method of claim 41, wherein the EMC comprises silica of about 50 wt % to about 90 wt %.

43. The method of claim 41, wherein the EMC has a thermal expansion coefficient of below about 50 ppm/° C. at a temperature range of less than a glass transition temperature.

44. The method of claim 22, wherein the molding layer is provided to cover the side surfaces of the semiconductor chip.

45. The method of claim 28, further comprising forming a passivation layer on the second surface of the polished semiconductor chip.

46. The method of claim 45, wherein the passivation layer has a thickness of about 20 μm to about 700 μm.

47. The method of claim 45, wherein the passivation layer is an EMC or a resin-based material.

48. The method of claim 45, wherein the passivation layer comprises substantially the same material as the molding layer.

49. The method of claim 28, further comprising forming a carrier layer on the second surface of the polished semiconductor chip.

50. The method of claim 49, wherein the carrier layer comprises at least one of a metal material, a ceramic material, or an organic material.

51. The method of claim 22, wherein if the semiconductor chip group includes a plurality of semiconductor chips, the semiconductor chip group has one of a wafer form, a strip form, and a carrier mounted form, the wafer form having scribe lanes between the semiconductor chips.

52. The method of claim 51, further comprising cutting the scribe lanes between the semiconductor chips and the molding layer to separate the semiconductor chip group into a plurality of semiconductor chip packages.

53. A method of fabricating a semiconductor package, the method comprising:
preparing a semiconductor chip package fabricated using the method of claim 22;
preparing a wiring substrate having a first surface and a second surface, the first surface on which the semiconductor chip package is mounted, the second surface facing the first surface; and
mounting the semiconductor chip package on the first surface of the wiring substrate.

54. The method of claim 53, further comprising forming wiring substrate solder balls on the second surface.
